(19) United States
(12) Patent Application Publication
(10) Pub. No.: US 2017/0154687 A1
(43) Pub. Date: Jun. 1, 2017

(54) SRAM-LIKE EBI STRUCTURE DESIGN AND IMPLEMENTATION TO CAPTURE MOSFET SOURCE-DRAIN LEAKAGE EARILER

(71) Applicant: GLOBALFOUNDRIES Inc., Grand Cayman (KY)

(72) Inventors: Zhigang Song, Hopewell Junction, NY (US); Oliver D. Patterson, Poughkeepsie, NY (US); Yun-Yu Wang, Poughquag, NY (US); Keith Kwong Hon Wong, Wappingers Falls, NY (US)

(21) Appl. No.: 14/954,151

(22) Filed: Nov. 30, 2015

(51) Int. Cl. G11C 29/04; H01L 21/768; H01L 23/58; H01L 21/66; H01L 27/11; H01L 27/108

(52) U.S. Cl. CPC G11C 29/04; H01L 27/11; H01L 27/10805; H01L 23/585; H01L 22/14; H01L 21/768; G11C 2029/0403

(57) ABSTRACT

A SRAM-like electron beam inspection (EBI) structure and method for determining defects in integrated circuits inline during the production process at a level that enables earlier detection during fabrication. Initial layers, such as active layer, poly gate and contact of an IC are first fabricated, and a conductive mesh with horizontal components is provided above the contact layers connecting contact nodes of the contact layers. Voltage contrast is observed during EBI to detect short-circuits, open-circuits, or leakage currents formed between the horizontal components of the conductive mesh and metallized islands placed therebetween.

### BACKGROUND OF THE DISCLOSURE

1. Field of the Disclosure

This disclosure relates generally to a method and structure for determining defects in integrated circuits, and more particularly to a method for determining leakage currents using electron beam inspection (EBI). More specifically, this disclosure relates to an inline inspection method performed earlier in the fabrication process to identify defects inline. The method requires the design of a test structure based on a repetitive pattern such as, for example, a static random access memory (SRAM) or dynamic random access memory (DRAM), that enables a user to view defects at an early stage in the processing via electron beam inspection at the passive voltage contrast mode.

2. Description of Related Art

The semiconductor industry has trended towards providing technology with process windows that are becoming smaller and more challenging for each manufacturer. It is essential that defects be identified as early in the fabrication process as possible to eliminate timely and costly redesign and/or work-around, and to qualify designs for full production runs.

Conventionally, most defects in semiconductor devices are detected at the wafer level, with the tests usually performed after the wafers have completed most of the wafer processing. This makes it extremely difficult to observe, find, and/or detect a defect at an early stage, and also results in a more difficult failure analysis. As an example, shorted paths may be difficult to pinpoint to a process step where the short occurred. This makes it difficult to correct the wafer design and/or change the process.

The fabrication of microelectronic devices requires a large number of processing steps, which makes it difficult to localize any particular defect to a given process layer—after many layers have been deployed. A great deal of effort is placed on minimizing process variation in order to achieve more robust and better controlled processes with higher yields using in-line inspection, metrology and test techniques. Devices are built into the wafer substrate which are then connected to each other to form circuits by way of multiple layers (easily 10) of interconnect wiring (typically copper). Each device is connected to a first level interconnect by contacts (typically tungsten studs). The devices are not electrically tested until many interconnects are in place. Electrical test structures are typically used to monitor process windows. In addition to electrical test, wafers can be inspected by a variety of optical defect inspection protocols. However, not all defect mechanisms can be detected, for instance gate source to drain leakage cannot be detected for bulk or SOT technology.

### SUMMARY OF THE DISCLOSURE

Bearing in mind the problems and deficiencies of the prior art, it is therefore an object of the present disclosure to provide a test method and structure to detect defects in wafer fabrication early in the fabrication sequence. Most importantly, in a preferred embodiment of the present disclosure, the contact layers and below are the same as those of the repeatable pattern, for example an SRAM or a DRAM (Herein the repeatable pattern will just be referred to as the SRAM embodiment, though other embodiments are applicable). In this manner, the test structure maintains the original SRAM density and structure, so that E-beam inspection on this structure will detect the same defect(s) as those which occurred at a contact level and below in a product SRAM device, as long as the critical area is sufficiently large enough. For this test structure, modification only occurs at the metal 1 layer and above.

it is another object of the present disclosure to provide a test method and structure that enables for the testing of localized defects in particular fabrication layers in an IC process.

The above and other objects, which will be apparent to those skilled in the art, are achieved in the present disclosure which is directed to a method for determining a defect during a semiconductor device fabrication, comprising: providing a semiconductor substrate having a plurality of initial layers forming contact nodes for electronic components, wherein the plurality of initial layers are patterned according to a final production design for the semiconductor device; providing a conductive mesh in the form of a predetermined metallized structure over a topmost layer of the plurality of initial layers, the conductive mesh including a plurality of horizontal components in electrical communication with the contact nodes; at least one conductive island situated adjacent at least one of the plurality of horizontal components; the conductive mesh forming a virtual ground for the contact nodes; exposing the semiconductor substrate with the conductive mesh to electron beam inspection; and observing contrast during exposure to the electron beam inspection.

The plurality of initial layers includes at least a first contact node or the first contact node and a second contact node.

The step of providing a conductive mesh includes patterning a first metallization (M1) layer over the plurality of initial layers, wherein at least one horizontal component of the conductive mesh is in electrical communication with at least one contact node on at least one of the plurality of initial layers.

The plurality of initial layers is formed on a semiconductor substrate by processes of lithography, deposition, removal, patterning, and modification of electrical properties including ion implantation, or any combination thereof. The plurality of initial layers may include the device (source, drain, gate) and contacts to the device.

The step of observing contrast during exposure to the electron beam inspection includes observing leakage current, conductive circuit shorts and/or opens.

The conductive mesh is big enough and serves as a virtual ground, or alternatively, may be connected to ground, or to the substrate.

In a second aspect, the present disclosure is directed to a test structure for detecting defects in a semiconductor wafer process, including: a semiconductor wafer having at least an initial layer for initiating FET design, the initial layers including substrate, active layer, poly gate layer, contact nodes etc.; a first metallization layer formed over the initial layers, the first metallization layer having horizontal components in electrical communication with the contact nodes, the horizontal components served as a virtual ground potential; and metallized islands adjacent the horizontal components, such that upon exposure to an electron beam inspection protocol, any defect in the FET design is observed in a voltage contrast image between the contact node and the metallized island.

The FET design includes a transistor network for a SRAM memory device.

The defect is observed as a contrast image during exposure to an electron beam inspection.

The first metallization layer is formed by patterning a first metallization layer over the plurality of initial layers, wherein at least one horizontal component of the first metallization layer is in electrical communication with at least one contact node on the at least one initial layer.

In a third aspect, the present disclosure is directed to a method for forming a test structure used for detecting a defect during the fabrication of a SRAM device, comprising: forming initial layers of a SRAM design on a semiconductor wafer, the initial layers formed on semiconductor substrate by processes of lithography, deposition, removal, patterning, and modification of electrical properties including ion implantation, or any combination thereof, the initial layers including transistor sections having substrate, active layer, poly gate and contact nodes etc.; forming a first metallization layer over the initial layers, the first metallization layer having horizontal components in electrical communication with the contact nodes, the horizontal components serve as a virtual ground potential; forming at least one conductive island situated adjacent at least one of the horizontal components; exposing the test structure to electron beam inspection such that a conducting path is formed between at least one contact node and the at least one conductive island; and observing voltage contrast of the conducting path during exposure to the electron beam inspection, such that leakage currents, open-circuits, and/or short-circuits are identified.

The first metallization layer and the at least one conductive island is formed by photoresist lithography and deposition protocols.

### BRIEF DESCRIPTION OF THE DRAWINGS

The features of the disclosure believed to be novel and the elements characteristic of the disclosure are set forth with particularity in the appended claims. The figures are for illustration purposes only and are not drawn to scale. The disclosure itself, however, both as to organization and method of operation, may best be understood by reference to the detailed description which follows taken in conjunction with the accompanying drawings in which:

FIG. 1 is a SEM image of a contact layer of a SRAM array structure having a glowing FET;

FIG. 2 depicts a portion of an exemplary test structure or M1 grid 14 connecting mesh node contacts to the nodes contacts of underlying layers of an integrated circuit, while M1 islands located between the horizontal conductive lines connect to V_{dd}, Vₛₛ, and bitline contacts;

FIG. 3 is an exemplary configuration of the underlying layers of an integrated circuit with nFET and pFET contact nodes;

FIG. 4 depicts the overlay of a portion of exemplary test structure on top of the underlying layers of FIG. 3, with designations for nFET and pFET constructions;

FIG. 5 depicts a schematic depiction of the complete M1 grid of the illustrative example of FIG. 2 with a glowing FET defect illuminated during electron beam inspection;

FIG. 6 depicts a SEM image of an open Vₛₛ contact, as shown by the dark M1 island, in the structure detected by EBI; and

FIG. 7 depicts a SEM image of a contact to poly gate short or source to drain short, as shown by bright M1 island in the structure detected by EBI.

### DESCRIPTION OF THE PREFERRED EMBODIMENT(S)

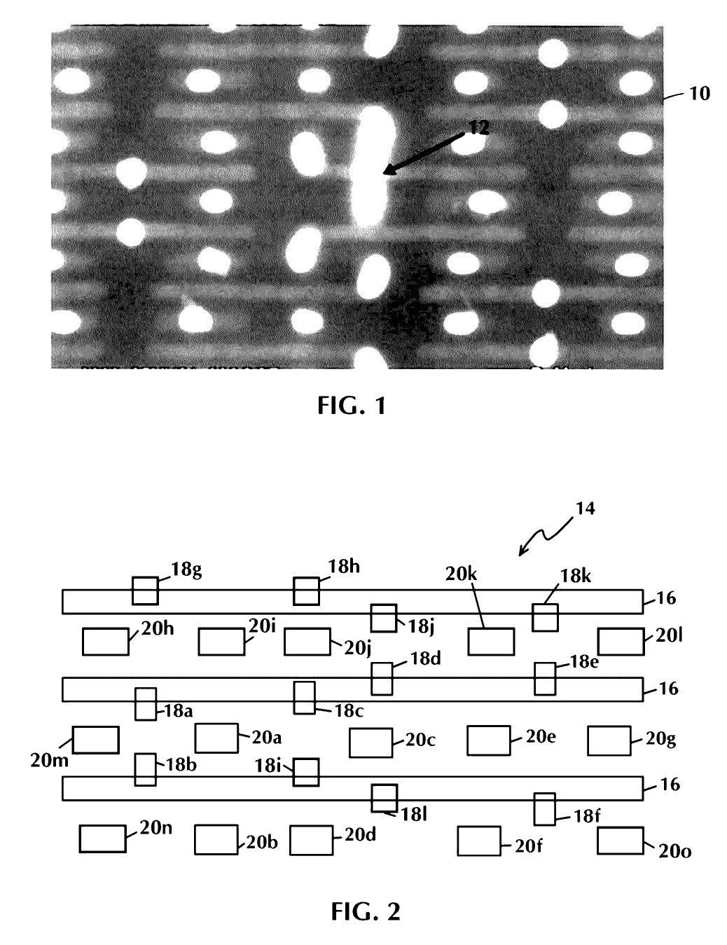

In describing the preferred embodiment of the present disclosure, reference will be made herein to FIGS. 1-7 of the drawings in which like numerals refer to like features of the disclosure.

The present disclosure introduces a test structure that facilitates the detection of defects localized to specific layers of a wafer fabrication process, and the process method steps for identifying these defects. In particular, attention is given to the fabrication process for SRAM devices, though other devices with repeatable patterns, such as memory cells including DRAMs would be amenable to this test structure and method.

Summarizing the wafer fabrication process, transistors on wafers, such as SRAM devices, DRAMS, and MOSFET devices, may be constructed in a general manner as follows: the wafer with an epitaxial layer may first be exposed to high temperature to grow an oxide layer (e.g., SiO₂) as a dielectric layer. The wafer is then coated with photo-resistant material. A lithography process exposes light through a mask pattern on the photo-resistant material. The light hardens the exposed portions of the photoresist, and the unhardened photo-resist is removed. An etching process is used to remove the oxide layer where photo-resist is absent, leaving a hardened oxide pattern on the wafer. Diffusion and implant processes may then be implemented to deposit dopant and ion to the exposed silicon to create regions with different conductivity of silicon semiconductor material. These lithography, diffusion, and implant processes are repeated several times to build transistors on the wafers. Metallization follows this process. Typically, a layer of aluminum or copper is deposited on the wafers in a metallization process. Excess metal on the wafer is etched away by another lithography process to provide desired interconnectivity. Another oxide layer is generally deposited on the deposited metal to isolate the first layer from the next. Each wafer is polished using a chemical mechanical planarization (CMP) process to provide the wafer a smooth surface. Then the next metal layer is deposited, patterned, and etched to create another connecting layer. The process is repeated for as many interconnect layers as are required for the chip design. In between the device and the metal layers is the contact layer which contains contacts connecting the device to a metal interconnect.

Testing these many process steps can be conducted at different stages of manufacture. For instance, IC design verification is preferably employed at the pre-production level on the wafer to characterize, debug, and verify new chip design to ensure it meets specifications. In-line parametric testing is generally done during wafer fabrication at the wafer level as a production process verification test, performed early on (near front-end of line, “FEOL”) to monitor the process. Wafer-sorting (probing) is performed at the wafer fabrication level to verify each die meets product specification. Bum-in reliability is typically performed at the packaged chip level where the ICs are powered up and tested at elevated temperature to stress the product to detect early failures. And final test is performed at the packaged chip level to verify product functionality (“functional testing”). The advantage of inspecting in-line is that it provides an opportunity to gather information regarding defects much earlier in the fabrication process. This allows for faster feedback for experiments, and. faster recognition if a problem is detected so that it can be fixed before too many lots are misprocessed.

Although it is understood that test structures for voltage contrast test of SRAM and other geometries are well known in the art, these geometries are all modified at the contact level and below. The present embodiments preserve the patterning of the structure up to the first metallization (M1) level, so that the defects are most representative of what would be observed during later functional testing of the actual SRAM chip.

Various fault measurements are considered for each element under test. For example, discrete transistors may include tests for leakage current, breakdown voltage, threshold voltage, or effective channel length; serpentine structures over oxide steps may require testing for continuity and bridging; resistivity structures may require measurements for film thickness; and contacts may include measurements for contact resistance and connections.

In certain instances, it is possible to have defects manifest themselves as visibly “glowing” in a SEM image. This generally represents an uncontained growth of a tungsten (W) contact in the active area, causing excessive FET source-drain leakage or a short, and presents a severe yield detractor during processing. Generally, this is caused by a compromise of a contact liner/barrier. Titanium nitride (TiN) is the most commonly used barrier material. Titanium nitride is a hard, dense, refractory material with unusually high electrical conductivity. The TiN barrier is utilized to protect the silicide layer from attacking by tungsten hexafluoride (WF₆) during contact tungsten (W) deposition. It has been shown that a thick TiN barrier can protect the underlying silicon (Si) and silicon-germanium (SiGe) material from WF₆ ingress during tungsten deposition; however, since TiN is a poor thermal expansion match to silicon, stress is often an issue if thick films are employed.

In addition, the TiN barrier is significantly resistive as compared to tungsten, and must be used sparingly to protection the titanium layer below. The titanium is used as a tungsten precursor. If an insufficient amount of TiN is used, the tungsten will react with the titanium and cause more problems. Thus, it is advantageous to have a thick TiN barrier to halt the reaction of titanium; however, a thick TiN barrier causes high contact resistance, resulting in low device performance. Optimization of TiN thickness is very important.

While current production methods, test, and failure analysis detect glowing FETs many steps into the fabrication process after the tungsten deposition process, the present test method and structure delineated in this disclosure allows for much earlier detection of these defects. Essentially, it provides a fast and sensitive scheme to catch glowing FET defects earlier inline.

Charged particle beam systems, such as electron beam inspection (EBI) systems, are increasingly utilized in advanced IC chip manufacturing. The systems have high resolution that can be used to detect tiny physical defects that are beyond detection of optical defect inspection systems. EBI systems are capable of detecting, through observation of a voltage contrast image, defects of electrical circuitry, such as open circuit, short circuit, or leakage on or underneath the wafer surface.

The present disclosure introduces a SRAM-like electron beam inspection (FBI) structure. In this test protocol, the contact layers (e.g., active contacts and poly gate contacts) and layers below are the same as any typical SRAM build.

The proposed structure is applied to the device at the M1 layer, where a conductive line connects the SRAM cell's internal node contacts (e.g., rectangular contact for pFET; contact node for nFET), and pass-gate contacts to form an M1 mesh. Other contacts like Vₛₛ, V_{dd}, and bitline contacts are connected to M1 islands.

FIG. 1 is a SEM image of a contact layer of a SRAM array structure 10 having a glowing FET 12, which in this instance caused a source-to-drain short in the FET. This image is taken by a scanning electron microscope (SEM).

At the contact-level and below, this test structure is the same as the originally designed SRAM structure; thus, the test structure will share the same defect as those happening at a normal production run for the SRAM device.

FIG. 2 depicts a portion of an exemplary test structure or M1 grid 14. The structure includes horizontal conductive lines 16 and vertical conductive lines 17 (not shown), which are connected to form a grid or mesh. Preferably the mesh is located at the M1 level. Connected to the mesh, preferably to the horizontal conductive lines 16 are mesh node contact structures 18a-l. Additionally, islands 20a-o in the M1 level are situated between horizontal conductive lines 16. These islands are not electrically connected to mesh node contact structures 18 or horizontal conductive lines 16 or vertical conductive lines 17. The mesh node contact structures are situated above the nFET and pFET contact nodes.

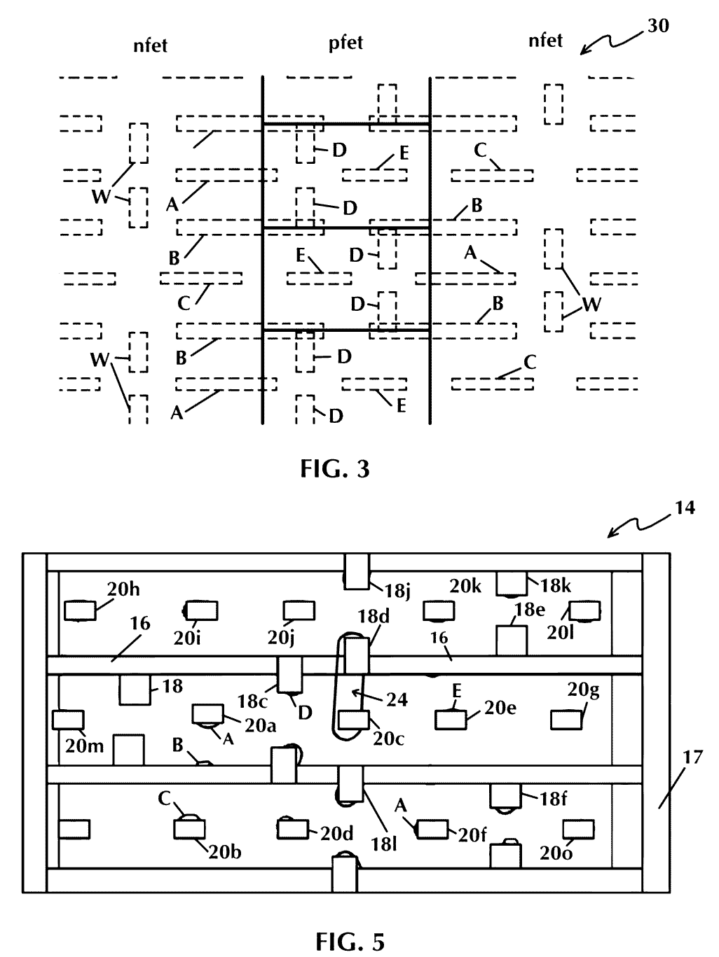

FIG. 3 is an exemplary configuration 30 of the underlying layers of an integrated circuit with nFET and pFET contact nodes. In this illustrative example, the following contacts are identified: node A is a bitline contact; node B is an nFET node contact; node C is a ground contact; node D is a pFET node contact; node E is a V_{dd} contact; and node W is a wordline contact.

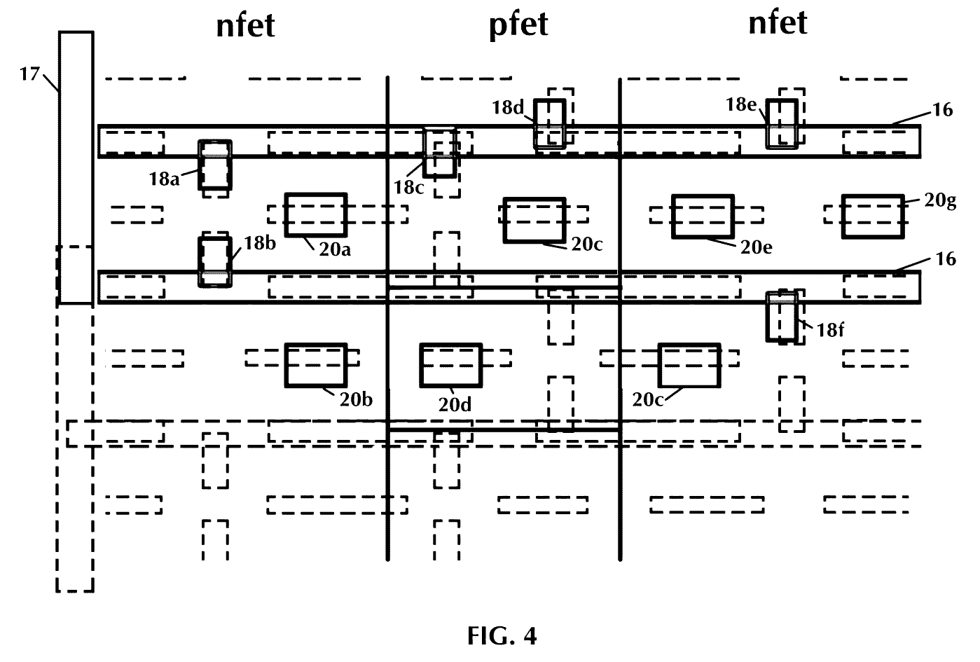

FIG. 4 depicts the overlay of a portion of exemplary test structure 14 on top of the underlying layers of FIG. 3, with designations for nFET and pFET constructions.

The M1 grid 14 is designed to be suitable for electron beam inspection. The M1 grid preferably consists of enough metal (or other conductive material) to act as a charge sink, and serve as a virtual ground. Preferably, the M1 grid is about at least twice as much total metal area compared to the floating contacts, and more preferably an order of magnitude larger. The more robust the virtual ground established by the M1 grid, the stronger the detection signal.

During electron beam inspection at a passive voltage contrast mode, the test structure serves as a charge sink because of its size, and will appear bright in contrast; whereas, the M1 island will be positively charged and appear dark in contrast.

FIG. 5 depicts a schematic depiction of a complete M1 grid 32 of the illustrative example of FIG. 2 depicting the location of a glowing FET defect 24 illuminated during electron beam inspection.

If a glowing FET defect 24 were to occur, the M1 island 22 associated with the glowing FET would short to the M1 island (in this case 20c) and appear bright in contrast under the E-beam inspection.

It should be further noted that although a glowing FET is used as an illustrative example of a defect, the methodology and structure delineated in the present disclosure is capable of detecting a source-drain short or leakage that may be caused by other defects, such as silicide encroachment in a FinFET.

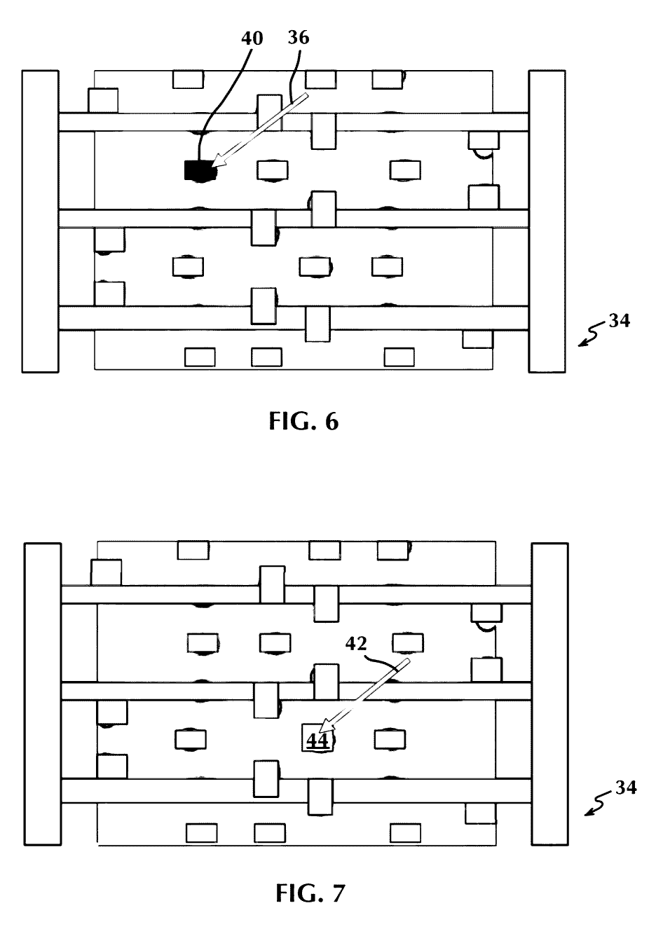

Another type of defect detectable by the test structure is show in FIG. 6 which depicts a SEM of an contact open defect 36 with a dark M1 island 40 as shown with the overlay grid 34. FIG. 7 depicts a SEM of a contact-poly short and source-drain short 42 showing a bright M1 island 44 in the overlay grid 34 by FBI. As noted in these figures, if there is an open, the observed contrast will be dark, signifying no current flow. If the contrast is grey in nature, there may be some limited leakage current.

A major benefit of having a test structure as disclosed is the utilization of the exact SRAM layout at the FEOL and MOL integration levels of production. Since underneath the test structure (M1 mesh) will reside the same fabrication levels that a production-ready SRAM device will employ, the same design or production defects will be observed at these integration levels. Furthermore, these defects are detected by electron beam inspection rather than functional tests. The detection of failures at the M1 level versus the more typical M4 level of the prior art allows the design of the SRAM (or other applicable device) to be verified and defects isolated at levels that were otherwise unachievable before. The defects are determined inline, not during later functional tests and failure analysis.

While the present disclosure has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present disclosure.

Thus, having described the disclosure, what is claimed is:

1. A method for determining a defect during a semiconductor device fabrication, comprising:
providing a semiconductor substrate having a plurality of initial layers up to a contact layer for electronic components, wherein said plurality of initial layers are patterned according to a final production design for said semiconductor device;
providing a conductive mesh in the form of a predetermined metallized structure over a topmost layer of said plurality of initial layers, such that a first metallization (M1) layer over said plurality of initial layers is patterned, said conductive mesh including a plurality of horizontal components in electrical communication with at least one contact node within said plurality of initial layers;
at least one conductive island situated adjacent at least one of said plurality of horizontal components;
said conductive mesh forming a ground for said at least one contact node;
exposing said semiconductor substrate with said conductive mesh to electron beam inspection; and
observing voltage contrast during exposure to said electron beam inspection.

2. The method of claim 1 wherein said at least one contact node includes a single contact node, or first and a second contact node.

3. The method of claim 1 wherein said step of patterning said first metallization (M1) layer over said plurality of initial layers, includes at least one horizontal component of said conductive mesh being in electrical communication with said at least one contact node on at least one of said plurality of initial layers.

4. The method of claim 1 wherein said plurality of initial layers are formed on said semiconductor substrate by processes of lithography, deposition, removal, patterning, and modification of electrical properties including ion implantation, or any combination thereof.

5. The method of claim 1 wherein said step of observing voltage contrast during exposure to said electron beam inspection includes observing leakage current, conductive circuit shorts and/or opens.

6. The method of claim 1 wherein said conductive mesh acts as a virtual ground or is connected to ground potential.

7. The method of claim 1 wherein said conductive mesh is connected to a semiconductor device substrate.

8. A test structure for detecting defects in a semiconductor wafer process, including:
a semiconductor wafer having at least an initial layer for initiating FET design, said initial layer including a substrate, active layer, and a plurality of contact nodes;
a first metallization layer formed over said initial layer, said first metallization layer having horizontal components in electrical communication with at least a first portion of said active layer, at least first portion of said plurality of contact nodes, or both; and
metallized island lands adjacent said horizontal components, said metal island lands in electrical communication with at least a second portion of said active layer, at least a second portion of said plurality of contact nodes, or both.

9. The test structure of claim 8 wherein said FET design includes a transistor network for a SRAM device.

10. The test structure of claim 8 wherein said FET design includes a transistor network for a DRAM device.

11. The test structure of claim 8 wherein said first metallization layer is formed by patterning a metal layer over said plurality of initial layers, wherein at least one of said horizontal components of said first metallization layer is in electrical communication with at least one of said contact nodes on said initial layer.

12. A method for forming a test structure used for detecting a defect during the fabrication of a SRAM device, comprising:
forming initial layers of a SRAM design on a semiconductor wafer, said initial layers formed on a semiconductor substrate by processes of lithography, deposition, removal, patterning, and modification of electrical properties including ion implantation, or any combination thereof, said initial layers including transistor sections having contact nodes;
forming a conductive mesh in the form of a predetermined metallized structure, said conducive mesh consisting of a first metallization layer over said initial layers, said first metallization layer having horizontal components in electrical communication with said contact nodes, said horizontal components serving as a ground or a virtual ground potential;
forming at least one conductive island situated adjacent at least one of said horizontal components;
exposing said test structure to electron beam inspection such that a conducting path is formed between at least one of said contact nodes and said at least one conductive island; and
observing voltage contrast of said conducting path during exposure to said electron beam inspection, such that leakage currents, open-circuits, and/or short-circuits are identified.

13. The method of claim 12 wherein said first metallization layer and said at least one conductive island is formed by photoresist lithography and deposition protocols.
